(19) United States
(12) Patent Application Publication
(10) Pub. No.: US 2015/0226784 A1
(43) Pub. Date: Aug. 13, 2015

(54) SEMICONDUCTOR DEVICE HAVING PLURAL MEMORY UNITS AND TEST METHOD THEREFOR

(71) Applicant: PS4 LUXCO S.A.R.L., Bons Malades (LU)

(72) Inventor: Atsushi Hatakeyama, Tokyo (JP)

(21) Appl. No.: 14/429,757

(22) PCT Filed: Sep. 20, 2013
(86) PCT No.: PCT/JP2013/005568

§ 371 Date: Mar. 19, 2015

(30) Foreign Application Priority Data
Sep. 25, 2012 (JP) 2012-210992

(51) Int. Cl. G01R 31/26; G01R 31/28; G11C 29/48; G11C 29/12; H01L 25/065; G11C 11/407

(52) U.S. Cl. CPC G01R 31/2601; H01L 25/0657; G11C 11/407; G11C 29/48; G11C 29/1201; G01R 31/28; H01L 2225/06596; H01L 2225/06541

(57) ABSTRACT

Disclosed herein is a semiconductor device that includes a semiconductor chip. The semiconductor chip includes a plurality of memory units each including a plurality of memory cells. The semiconductor chip further includes a plurality of pad groups each coupled to a corresponding one of the memory units and each including a plurality of pads, and a plurality of test pads each coupled in common to the memory units. In a normal operation mode, the test pads are free from signals and the pads of each of the pad groups are supplied with signals such that normal operations are performed respectively on the memory units. In a test operation mode, the test pads are supplied with test signals and the pads of each of the pad groups are free from signals such that test operations are performed respectively on the memory units.

### BACKGROUND

1. Field of the Invention

The present invention relates to a semiconductor device and a test method therefor, and more particularly relates to a semiconductor device having a structure in which a plurality of semiconductor chips each having a plurality of memory units are stacked and a test method therefor.

2. Description of Related Art

Speed-up and power consumption reduction are demanded in semiconductor devices such as a DRAM (Dynamic Random Access Memory). To meet this demand, a stacked semiconductor device in which semiconductor chips are stacked and connected with each other using through silicon vias has been developed in recent years.

The through silicon via is a conductive path passing through a semiconductor substrate such as a silicon substrate in a direction of stacking of the semiconductor chips. Use of the through silicon vias enables to reduce the package size and to shorten the connection distances between the semiconductor chips as compared to a case where wire bonding is used and accordingly speed-up and power consumption reduction can be achieved in the stacked semiconductor device. Japanese Patent Application Laid-open No. 2012-008881 discloses an example of such a stacked semiconductor device.

A Wide I/O DRAM is one type of the stacked semiconductor devices. The Wide I/O DRAM is a semiconductor device expected to be used in smartphones or tablet terminals rapidly spreading in recent years and has a characteristic that each of semiconductor chips constituting layers has four channels (memory units).

Terminal regions for the respective channels and a plurality of test pads are provided on the principal surface of each of the semiconductor chips included in the Wide I/O DRAM. The terminal regions are provided also on the rear surface of each semiconductor chip. In the terminal region, various terminals (such as a data input/output terminal, a command input terminal, and an address input terminal) of the corresponding channel and various terminals for testing (such as a test-data input/output terminal, a test command terminal, and a test address terminal; hereinafter generally referred to as “direct access terminals”) are arranged. The terminals on the rear surface and the terminals on the principal surface correspond one-to-one and are electrically connected by through silicon vias, respectively. The terminals on the principal surface are electrically connected to corresponding ones of the terminals provided on the rear surface of an underlying different semiconductor chip. The test pads are provided to correspond one-to-one with the direct access terminals and are connected with the corresponding direct access terminals in the semiconductor chips. In the present specification, a test on a semiconductor chip in a unit or a test in a semifinished state where semiconductor chips are stacked and a controller chip is not stacked is specifically explained below. The test is performed in a state where a probe needle of a tester is brought into contact with the test pads and a command and an address for testing are supplied from the tester to the semiconductor chips through the test pads and the direct access terminals. However, in a state of the stacked semiconductor device having the semiconductor chips and the controller chip stacked and packaged, at least some of the direct access terminals are connected to external terminals of the stacked semiconductor device without subjected to substantial processing on the controller chip. Therefore, for example, by supplying a command and an address for testing to the semiconductor chips through external terminals corresponding to the direct access terminals in a state where the stacked semiconductor device is mounted on a test board or the like, the same test as that performed via the test pads can be also performed on a finished stacked semiconductor device.

The test pads are pads for being brought into contact with the probe needle of the tester and thus need a larger installation area than the terminals in the terminal region. Therefore, the number of the test pads that can be installed on the principal surface of the semiconductor chip is limited and the test pads cannot be provided for each channel. Accordingly, the test pads (and the direct access terminals) are provided for four channels in common. As a result, the test cannot be performed in a state where only one channel is operated and thus the conventional test is always performed in a state where the four channels are operated.

However, a defective product may be missed in such a test method. For example, even in a case where satisfaction of an operation current of each channel with a specification is to be confirmed, it is only possible to evaluate whether the whole current obtained when the four channels are simultaneously operated is four times a current specification of one channel and, as a result, such a defective product that the current is too large only in a certain channel and the current is too small in the remaining three channels may be missed. Therefore, realization of a test for each channel has been desired.

### SUMMARY

In one embodiment, there is provided a semiconductor device that includes a semiconductor chip. The semiconductor chip includes a plurality of memory units each including a plurality of memory cells. The semiconductor chip further includes a plurality of pad groups each coupled to a corresponding one of the memory units and each including a plurality of pads, and a plurality of test pads each coupled in common to the memory units. In a normal operation mode, the test pads are free from signals and the pads of each of the pad groups are supplied with signals such that normal operations are performed respectively on the memory units. In a test operation mode, the test pads are supplied with test signals and the pads of each of the pad groups are free from signals such that test operations are performed respectively on the memory units.

### BRIEF DESCRIPTION OF DRAWINGS

The above features and advantages of the present invention will be more apparent from the following description of certain preferred embodiments taken in conjunction with the accompanying drawings, in which:

FIG. 1A is a schematic cross-sectional view of a semiconductor device 1 according to a first embodiment of the present invention;

FIG. 1B is a schematic cross-sectional view to explain a structure of a composite semiconductor device 10 into which the semiconductor device shown in FIG. 1 is integrated;

FIGS. 2A and 2B show connection states of the through substrate vias TSV provided in each of the semiconductor chips C1 to C4 shown in FIG. 1A;

FIG. 3 is a cross-sectional view of the through substrate via TSV1 shown in FIG. 2A;

FIG. 4 is a cross-sectional view of the through substrate vias TSV2 shown in FIG. 2B;

FIG. 5 is a plan view of the bottom surface C1a of the semiconductor chip C1 shown in FIG. 1A;

FIGS. 6A to 6C show connection states of the through substrate via TSV provided on the controller chip C0 shown in FIG. 1B;

FIG. 7 is a schematic block diagram showing functional blocks of the semiconductor chip C2 shown in FIG. 1A;

FIG. 8 is a diagram partially showing internal configurations of the input circuit group 51 and the control circuit 52 each shown in FIG. 7;

FIG. 9 shows an internal configuration of the channel-specific test-mode control circuit 56 shown in FIG. 7;

FIGS. 10 and 11 are flowcharts showing a processing flow in a case where the chip unit test or the post-stack test on the semiconductor device 1 shown in FIG. 1A is performed;

FIG. 12 is a schematic block diagram showing functional blocks of the semiconductor chip C2 included in the semiconductor device 1 according to a second embodiment of the present invention; and

FIG. 13 is a diagram partially showing internal configurations of the input circuit group 51 and the control circuit 52 included in the channel Ch_a of the semiconductor device 1 according to a third embodiment of the present invention.

### DESCRIPTION OF EMBODIMENTS

The invention will be now described herein with reference to illustrative embodiments. Those skilled in the art will recognize that many alternative embodiments can be realized using the teachings of the present invention and that the invention is not limited to the embodiments illustrated for explanatory purposes.

### First Embodiment

A semiconductor device and a test method therefor according to preferred embodiments of the present invention will now be explained in detail with reference to the drawings.

In the following explanations, an overall configuration of the semiconductor device 1 is described first, and then characteristic configurations of the present embodiment are described in detail.

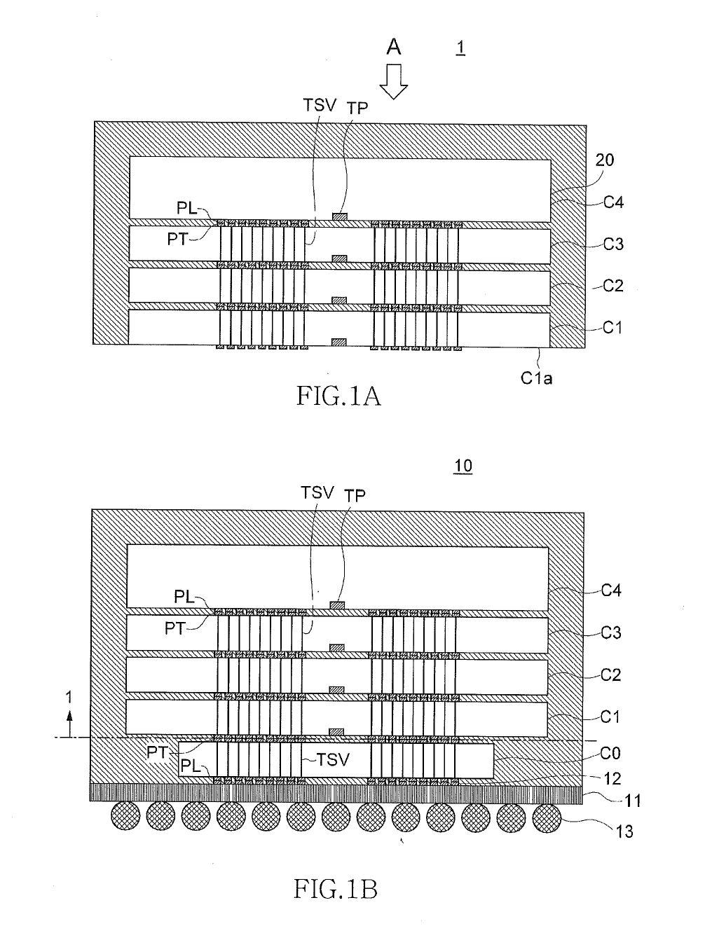

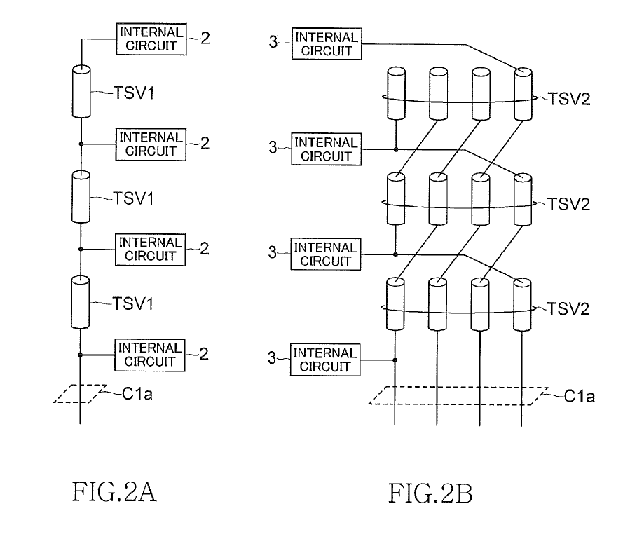

Referring now to FIG. 1A, the semiconductor device 1 according to the first embodiment is a so-called wide IO DRAM having a configuration in which three semiconductor chips C1 to C3 each having terminals PL, through substrate vias TSV, and terminals PT and a semiconductor chip C4 having terminals PL while having no through substrate via TSV and no terminal PT are stacked sequentially in this order from the bottom. A plurality of through substrate vias TSV may be referred to as a plurality of penetration electrodes. The semiconductor chips C1 to C3 are three semiconductor chips having the same function and the same configuration and manufactured with the same mask. The semiconductor chip C4 substantially has the same function and the same configuration as the semiconductor chips C1 to C3 except that the semiconductor chip C4 does not have a through substrate via TSV and a terminal PT.

Each of the semiconductor chips C1 to C4 functions as a so-called DRAM, including a memory cell array and peripheral circuits of the memory cell array (not shown in FIG. 1A). The peripheral circuits include a data input/output circuit that performs input and output of data between the memory cell array and outside, a control circuit that controls the input and output operations of the data in response to a command issued from outside. Hereafter, the memory cell array and the peripheral circuits may be collectively referred to as “internal circuit” in some cases. The semiconductor chips C1 to C4 are sealed with a resin in a state of being stacked, and function as a memory device that is integrally packaged.

The semiconductor device 1 is a semifinished product, which is provided to an end user as a composite semiconductor device 10 in which the semiconductor device 1 is stacked on a package substrate 11 (an interposer) with a controller chip C0 as shown in FIG. 1B. The controller chip C0 is a semiconductor chip in which a logic circuit is formed on a rear surface or a principal surface of a semiconductor substrate, and is also referred to as “SOC (System On Chip)”. The controller chip C0 and the semiconductor device 1 are integrally sealed with a resin as shown in FIG. 1B. Therefore, a principal surface C1a of the semiconductor chip C1 is out of the end user's sight. A configuration of the composite semiconductor device 10 is described in detail later.

As shown in FIG. 1A, each of the semiconductor chips C1 to C4 includes a semiconductor substrate (a silicon substrate) 20, and the internal circuit mentioned above is formed on a principal surface (a bottom surface) of the semiconductor substrate 20. Regarding the semiconductor chips C1 to C3, input/output terminals PT and input/output terminals PL are formed on the principal surface and the rear surface, respectively. The terminal PL and the terminal PT are connected to each other with a through substrate via TSV that penetrates through the semiconductor substrate 20 as shown in the diagram. On the other hand, regarding the semiconductor chip C4, input/output terminals PL on the rear surface and through substrate vias TSV are not formed while input/output terminals PT are formed on the principal surface.

The input/output terminals PT on the rear surface of the semiconductor chip C4 and the through substrate vias TSV are not provided because the semiconductor chip C4 is the uppermost semiconductor chip in the semiconductor device 1 and thus it is unnecessary to supply signals supplied from the terminals PT of the semiconductor chip C3 to another semiconductor chip. When the through substrate vias TSV and the terminals PT are not formed in the semiconductor chip C4 in this way, the semiconductor chip C4 can be thicker than the semiconductor chips C1 to C3 as exemplified in FIG. 1A. As a result, during manufacturing of the semiconductor device 1, deformation of the chips due to a thermal stress (a thermal stress generated when the semiconductor chips C1 to C4 are stacked) can be suppressed. However, a semiconductor chip having the same structure as that of the semiconductor chips C1 to C3 can be of course used as the semiconductor chip C4.

The terminals PL and the internal circuit are connected with each other via interconnections provided on the principal surface of each semiconductor chip. The terminals PT of the semiconductor chips C1 to C3 are in contact with the terminals PL of different semiconductor chips on layers located just above. Accordingly, the input/output terminals of the semiconductor chips C1 to C4 are drawn to the principal surface C1a of the semiconductor chip C1 on the lowermost layer.

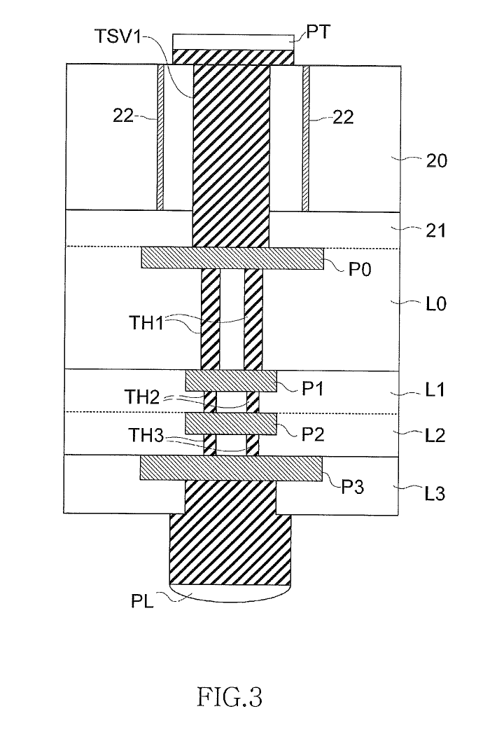

The connection states of the through substrate vias TSV include two types shown in FIG. 2A and FIG. 2B. Note that the terminals PT and PL are omitted from FIGS. 2A and 2B. In the following explanations, the through substrate vias TSV corresponding to FIG. 2A and FIG. 2B are referred to as “through substrate via TSV1” and “through substrate via TSV2”, respectively.

The through substrate via TSV1 shown in FIG. 2A is short-circuited with the through substrate via TSV1 on another layer provided at the same position in a planar view in the stacking direction, that is, when viewed in a direction of an arrow A shown in FIG. 1A. That is, as shown in FIG. 2A, the through substrate vias TSV1 provided at the same position in the planar view are short-circuited with each other, and a single current path is formed by these through substrate vias TSV1. This current path is connected to an internal circuit 2 of each of the semiconductor chips C1 to C4. Therefore, an input signal (a command signal, an address signal, a clock signal, and the like) supplied to the current path from outside via the principal surface C1a of the semiconductor chip C1 is commonly input to the internal circuits 2 of the semiconductor chips C1 to C4. Furthermore, an output signal (data and the like) supplied to the current path from the internal circuit 2 of each of the semiconductor chips C1 to C4 undergoes a wired-OR operation, and is output to outside from the principal surface C1a of the semiconductor chip C1.

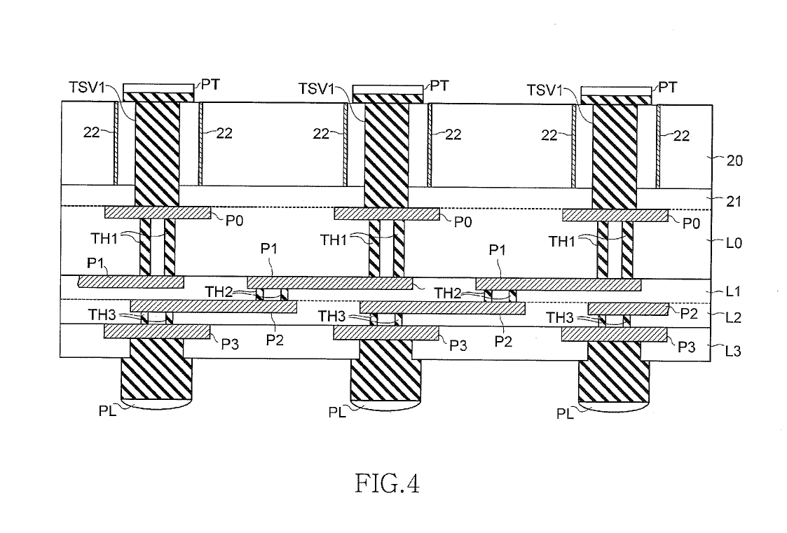

As shown in FIG. 3, the through substrate via TSV1 is formed so as to penetrate the semiconductor substrate 20 and an inter-layer insulation film 21 on a surface of the semiconductor substrate 20. An insulation ring 22 is provided around the through substrate via TSV1, by which insulation is secured between the through substrate via TSV1 and a transistor area (an area where a transistor constituting the internal circuit is formed). The insulation ring 22 can be doubly provided, with which a capacitance between the through substrate via TSV1 and the semiconductor substrate 20 can be reduced.

The lower end of the through substrate via TSV1 is connected to the terminal PL (a front surface bump) provided on the principal surface of the semiconductor chip via pads P0 to P3 provided on each of wiring layers L0 to L3 and a plurality of through-hole electrodes TH1 to TH3 connecting between the pads. On the other hand, the upper end of the through substrate via TSV1 is connected to the terminal PT (a rear surface bump) of the semiconductor chip. The terminal PT is connected to the terminal PL of the semiconductor chip on the upper layer. With this configuration, two through substrate vias TSV1 provided at the same position in the planar view are short-circuited with each other. Connection with the internal circuit 2 shown in FIG. 2A is made via an internal wiring line (not shown) drawn from the pads P0 to P3 respectively provided on the wiring layers L0 to L3.

The through substrate via TSV2 shown in FIG. 2B is short-circuited to the through substrate via TSV2 on another layers provided at a different position in the planar view. Specifically, in each of the semiconductor chips C1 to C3, four (that is, the number of layers) through substrate vias TSV2 are provided at the same positions in the planar view. The through substrate via TSV2 provided at a predetermined position in the planar view from among the four through substrate vias TSV2 (in FIG. 2B, the through substrate via TSV2 at the leftmost side) is connected to an internal circuit 3 provided in the same semiconductor chips C1 to C3. There through substrate vias TSV2 selected from each of the semiconductor chips C1 to C3 one by one, which are provided at a different position in the planar view each other, are short-circuited each other, by which four current paths each of which leads from the semiconductor chip C4 to the semiconductor chip C1 are formed. A lower end of each current path is exposed to the principal surface C1a. The current path among the four current paths which is not connected to any one of the internal circuits 3 in the semiconductor chips C1 to C3 is connected to an internal circuit 3 in the semiconductor chip C4 at its upper end. Therefore, via the current paths, it becomes possible to input information from outside selectively to the internal circuit 3 of each layer. A specific example of such information includes a chip select signal and a clock enable signal, which are described later.

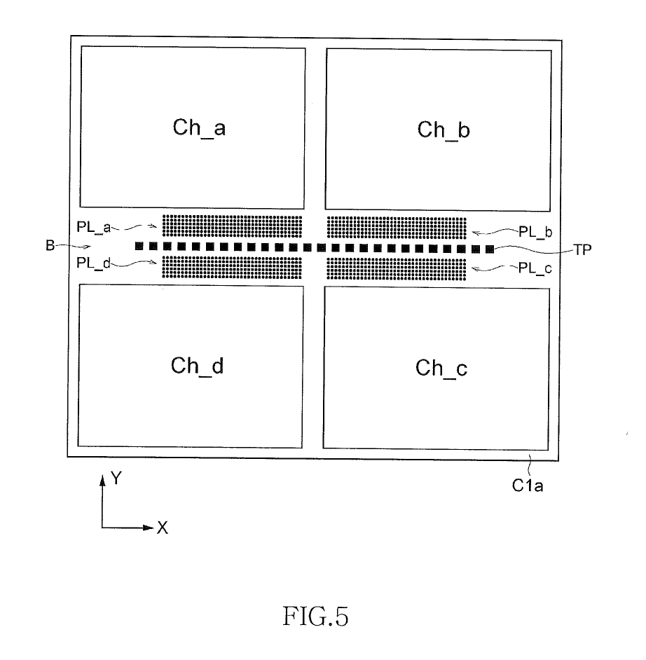

As shown in FIG. 4, the through substrate via TSV2 is different from the through substrate via TSV1 in that the pads P1 and P2 located at the same planar position are not connected to each other with the through-hole electrode TH2, but the pads P1 and P2 located at different positions are connected to each other with the through-hole electrode TH2. Although only three through substrate vias TSV2 are shown in FIG. 4, the actual number of through substrate vias TSV2 is the number of semiconductor chips (four) per signal in each of the semiconductor chips C1 to C3.

Referring back to FIG. 1A, a test pad TP is further provided on the principal surface of the semiconductor substrate of each of the semiconductor chips C1 to C4 along with the terminals PL. The test pad TP is a pad for contacting a probe needle of the tester when testing the semiconductor chip on the wafer level, which is connected to any one of the terminals PL provided on the same principal surface with a wiring line in the plane.

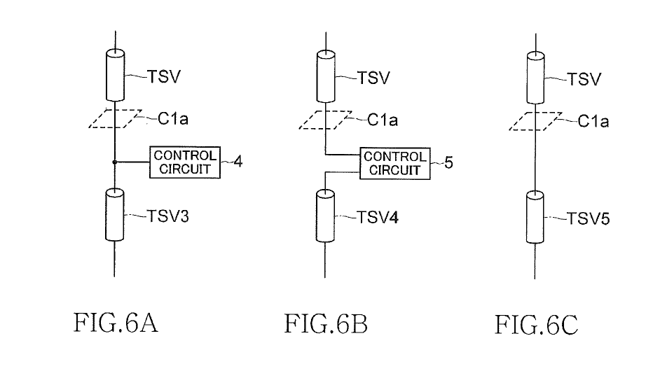

As shown in FIG. 5, four channels Ch_a to Ch_d, a plurality of terminals PL_a to PL_d corresponding respectively to the channels Ch_a to Ch_d, and a plurality of test pads TP are provided on the principal surface C1a of the semiconductor chip C1. The channels Ch_a to Ch_d are semiconductor circuits configured to transmit and receive various signals including a command signal, an address signal, a data signal, and the like with outside independently of each other, and each of them functions as a single DRAM. That is, the semiconductor chip C1 is configured to perform various operations as a DRAM, such as a read operation, a write operation, a refresh operation, and the like, for each channel independently. Although not shown in FIG. 5, the principal surfaces of other semiconductor chips C2 to C4 have the same configuration as the principal surface C1a of the chip C1.

The terminals PL_a to PL_d each include various terminals (such as the data input/output terminal, the command input terminal, and the address input terminal) of the corresponding channel and various terminals for testing (the direct access terminals; specifically, the test-data input/output terminal, the test command terminal, the test address terminal, and the like). The former type of the terminals is connected only to the corresponding channel and the latter type of the terminals (the direct access terminals) is connected to the channels Ch_a to Ch_d in common. Therefore, a signal supplied from outside to the direct access terminals is input to all of the channels Ch_a to Ch_d in common. The direct access terminals are provided to correspond one-to-one with the test pads TP and are connected with the corresponding test pads in the semiconductor chip.

As shown in FIG. 5, the channels Ch_a and Ch_b are arranged on one side in a Y direction, and the channel Ch_c and the channel Ch_d are arranged on the other side in the Y direction. A terminal area B is provided between the channels Ch_a and Ch_b and the channels Ch_c and Ch_d, and the terminals PL_a to PL_d and the test pads TP are arranged in the terminal area B. Specifically, the terminals PL_a to PL_d are respectively arranged in a plurality of arrays near the corresponding channels in the terminal area B, and the test pads TP are arranged in a row in an area between the terminals PL_a and PL_b and the terminals PL_c and PL_d. As shown in FIG. 5, dimensions and intervals of the test pads TP are set to be larger than those of the terminals PL. This arrangement facilitates that the probe needle makes contact with the test pads TP. In a test operation mode, performing the test of the semiconductor device 1 by using the test pad TP having the above configuration makes it possible to perform the test without causing any damage on the terminals PL and the through substrate vias TSV of the semiconductor chip.

The configuration of the composite semiconductor device 10 is described in detail below with reference to FIG. 1B. The same terminals PT and PL as those of the semiconductor chips C1 to C4 are provided on the rear surface and the principal surface of the controller chip C0, respectively. The terminal PT of the chip C0 is connected to the terminal PL of the semiconductor chip C1. On the other hand, the terminal PL of the chip C0 is connected to a bump electrode 12 (described later) provided on the rear surface of the package substrate 11. As shown in FIG. 1B, the through substrate via TSV is also provided on the semiconductor substrate of the controller chip C0, and the terminals PT and PL and the internal circuit of the controller chip C0 are connected to each other with the through substrate via TSV.

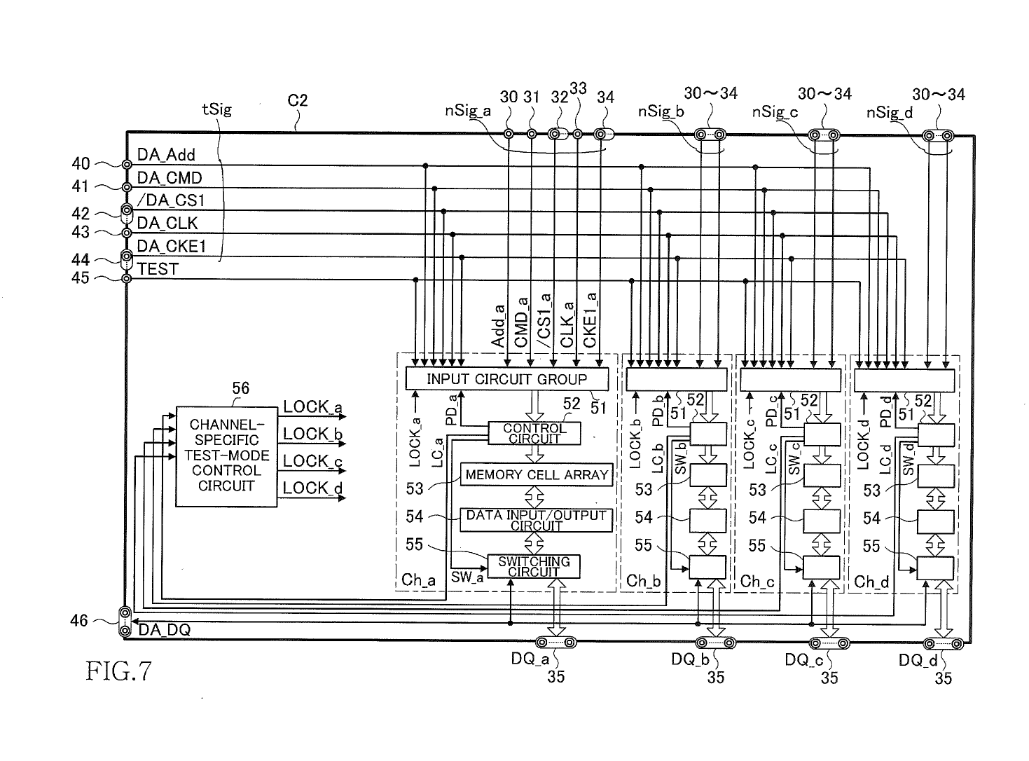

The connection states of the through substrate via TSV provided on the controller chip C0 include three types as respectively shown in FIG. 6A to 6C. Note that the terminals PT and PL are omitted from FIGS. 6A to 6C. In the following explanations, the through substrate vias TSV corresponding to the three types are referred to as “through substrate via TSV3”, “through substrate via TSV4”, and “through substrate via TSV5”, respectively. Through substrate vias TSV other than the through substrate vias TSV3 to TSV5 shown in FIGS. 6A to 6C are the through substrate vias TSV provided on the semiconductor chip C1.

The through substrate via TSV3 shown in FIG. 6A is connected to the through substrate via TSV of the semiconductor chip C1 and also to a control circuit 4 of the controller chip C0. The through substrate via TSV3 having this configuration is used as a power-supply line, for example.

The through substrate via TSV4 shown in FIG. 6B is connected to the through substrate via TSV of the semiconductor chip C1 via a control circuit 5 provided on the controller chip C0. With this configuration, for example, the controller chip C0 is configured to generate an internal command by decoding a command input to the composite semiconductor device 10 via the bump electrode 12 (FIG. 1B) which is described later from outside and output the generated internal command to the semiconductor chips C1 to C4.

The through substrate via TSV5 shown in FIG. 6C is connected to the through substrate via TSV of the semiconductor chip C1, but not connected to any circuit in the controller chip C0. Providing the through substrate via TSV5 having this configuration enables input and output of data between the semiconductor chips C1 to C4 and outside in a direct manner.

Referring back to FIG. 1B, the package substrate 11 is provided to convert a terminal pitch, in which the bump electrodes 12 that are respectively connected to the terminals PL of the controller chip C0 are provided on the rear surface and bump electrodes 13 of the same number as the number of the bump electrodes 12 on the rear surface are formed on the principal surface with an area and an interval larger than those of the bump electrode 12 on the rear surface. The bump electrodes 12 on the rear surface and the bump electrodes 13 on the principal surface are connected to each other on a one-to-one basis with a through substrate via (not shown) that penetrates the package substrate 11. The composite semiconductor device 10 is mounted on a motherboard of a computer, a mobile phone, or the like through the bump electrodes 13 in a flip-chip manner.

When the semiconductor device 1 explained above is to be manufactured, an operation test for a semiconductor chip in a unit (hereinafter, “chip unit test”) is performed at a stage before stacking the semiconductor chips C1 to C4. This chip unit test is performed by supplying various test signals from a tester in a state where a probe needle of the tester is brought into contact with the test pads TP provided on the principal surface of the semiconductor chip to be tested. An operation test of the semiconductor device 1 at a stage of the semifinished product shown in FIG. 1A (hereinafter, “post-stack test”) is also performed. This post-stack test is performed by supplying various test signals from the tester in a state where the probe needle of the tester is brought into contact with the test pads provided on the principal surface C1a of the semiconductor chip C1 located on the lowermost layer. The test signals in this case include a test-chip select signal for selecting any one of the semiconductor chips C1 to C4 as a test target. The semiconductor device 1 is characterized by a fact that the test for each channel is realized when the chip unit test and the post-stack test are performed. This characteristic is explained below in detail.

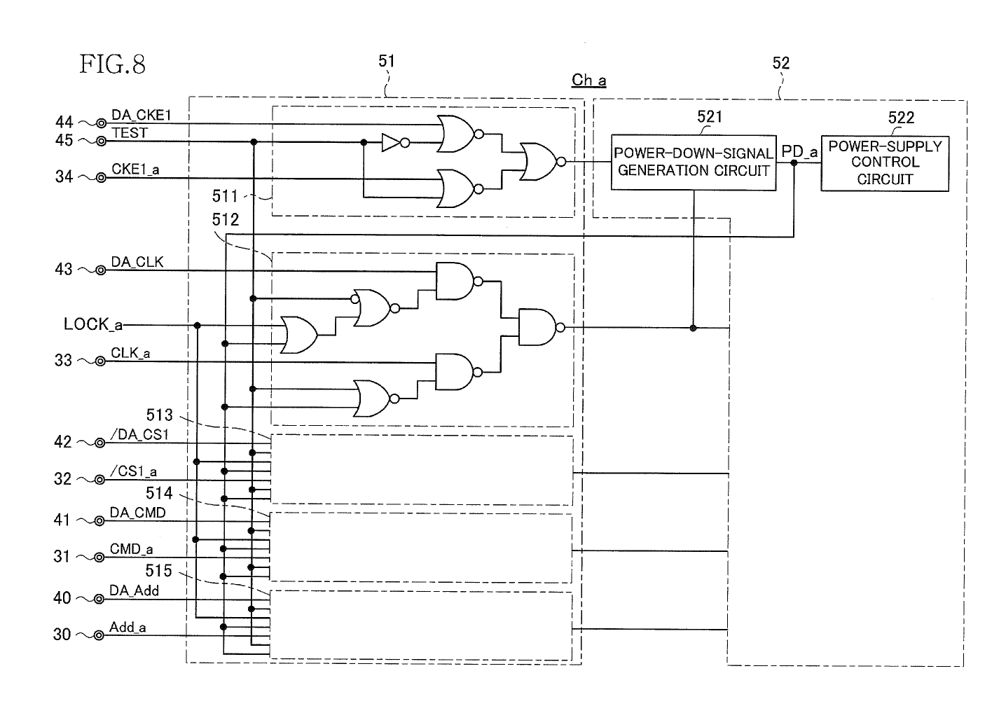

As shown in FIG. 7, the semiconductor chip C2 has an address terminal 30, a command terminal 31, a chip select terminal 32, a clock terminal 33, a clock enable terminal 34, and a data input/output terminal 35 with respect to each channel, and has a test address terminal 40, a test command terminal 41, a test-chip select terminal 42, a test clock terminal 43, a test-clock enable terminal 44, a test-signal input terminal 45, and a test-data input/output terminal 46 in common for the four channels Ch_a to Ch_d. These are all the terminals PL shown in FIG. 1A and, among these, the chip select terminal 32, the clock enable terminal 34, the test-chip select terminal 42, and the test-clock enable terminal 44 are connected to the through substrate via TSV2 mentioned above. Other terminals are connected to the through substrate via TSV1 mentioned above. Not all terminals are shown in FIG. 7 and various other terminals are provided in the semiconductor chip C2. The various terminals include a reset terminal for supplying a test reset signal to reset the semiconductor chip C2 at the time of testing. Although not shown in FIG. 7, other semiconductor chips C1, C3, and C4 have the same configuration as the semiconductor chip C2.

The address terminal 30, the command terminal 31, the chip select terminal 32, the clock terminal 33, and the clock enable terminal 34 are supplied with various control signals (a normal signal group nSig) after the semiconductor device 1 as a semifinished product is incorporated into a composite semiconductor device 10 as a finished product. The data input/output terminal 35 is a terminal to/from which a data signal DQ is input/output after the semiconductor device 1 as the semifinished product is incorporated into the composite semiconductor device 10 as the finished product. Because these terminals are not connected to the test pads TP, these terminals cannot be accessed from outside before the semiconductor device 1 is incorporated into the composite semiconductor device 10, that is, in a state where the principal surface C1a of the semiconductor chip C1 is exposed (hereinafter, this state is referred to as “pre-assembly”). The letter “a” attached at the tail of a signal name in FIG. 7 indicates that the relevant signal is supplied to the channel Ch_a. The same applies to signs “b” to “d”. The same also applies to signals described later.

On the other hand, the test address terminal 40, the test command terminal 41, the test-chip select terminal 42, and the test clock terminal 43 are terminals (test terminals) are supplied with various control signals (a test signal group tSig) when the chip unit test and the post-stack test mentioned above are performed. The test-data input/output terminal 46 is a terminal (a test terminal) to/from which a data signal DA_DQ for testing is input/output when the chip unit test and the post-stack test are performed. These test terminals are connected to the test pads TP on a one-to-one basis as mentioned above. Therefore, these test terminals can be accessed by an external tester at a pre-assembly stage.

The test-signal input terminal 45 is supplied with a test signal TEST indicating that the chip unit test or the post-stack test is to be performed. Also the test-signal input terminal 45 is connected to the test pad TP and accordingly an activation state of the test signal TEST can be controlled by the external tester. The test-signal input terminal 45 is configured in such a manner that the relevant potential (=the activation state of the test signal TEST) keeps a deactivated state (a low level) during normal operations when the external tester is not connected thereto (when the chip unit test and the post-stack test are not performed; the same applies in the following descriptions).

The channels Ch_a to Ch_d are each configured to have an input circuit group 51, a control circuit 52, a memory cell array 53, a data input/output circuit 54, and a switching circuit 55 as shown in FIG. 7. The input circuit group 51 is a circuit that selects a control signal to be supplied to the control circuit 52 from among the various control signals supplied through the terminals mentioned above. The control circuit 52 is a circuit that accesses the memory cell array 53 in response to a command signal and an address signal input through the input circuit group 51, thereby realizing read/write from/to the memory cell array 53, and the like. The memory cell array 53 has a configuration in which a memory cell having a cell capacitor and a cell transistor is arranged at each of intersections between a plurality of word lines and a plurality of bit lines and is configured to include a row decoder that activates one of the word lines in response to a control of the control circuit 52, a column decoder that connects one of the bit lines to the data input/output circuit 54 in response to the control of the control circuit 52, and the like. The data input/output circuit 54 serves to output read data that is read from the memory cell array 53 to outside at the time of read and to supply write data that is supplied from outside to the memory cell array 53 at the time of write. The switching circuit 55 performs a process of connecting one of the data input/output terminal 35 and the test-data input/output terminal 46 to the data input/output circuit 54 and disconnecting the other terminal from the data input/output circuit 54.

A channel-specific test-mode control circuit 56 (test control circuit) is also provided in common for the four channels Ch_a to Ch_d in the semiconductor chip C2. The channel-specific test-mode control circuit 56 is used only in a test operation mode. In a test operation mode, the channel-specific test-mode control circuit 56 serves, when a lock control signal (a signal composed of at least some of the signals supplied through the test terminals, respectively) for designating a channel to be locked is supplied from the tester, to receive the lock control signal via the control circuit 52 of each channel and stop an operation of one or plural channels in response to the received lock control signal. Stop (lock) of the operations of the channels is realized by lock signals LOCK_a to LOCK_d generated by the channel-specific test-mode control circuit 56 for the respective channels. Details thereof are explained later.

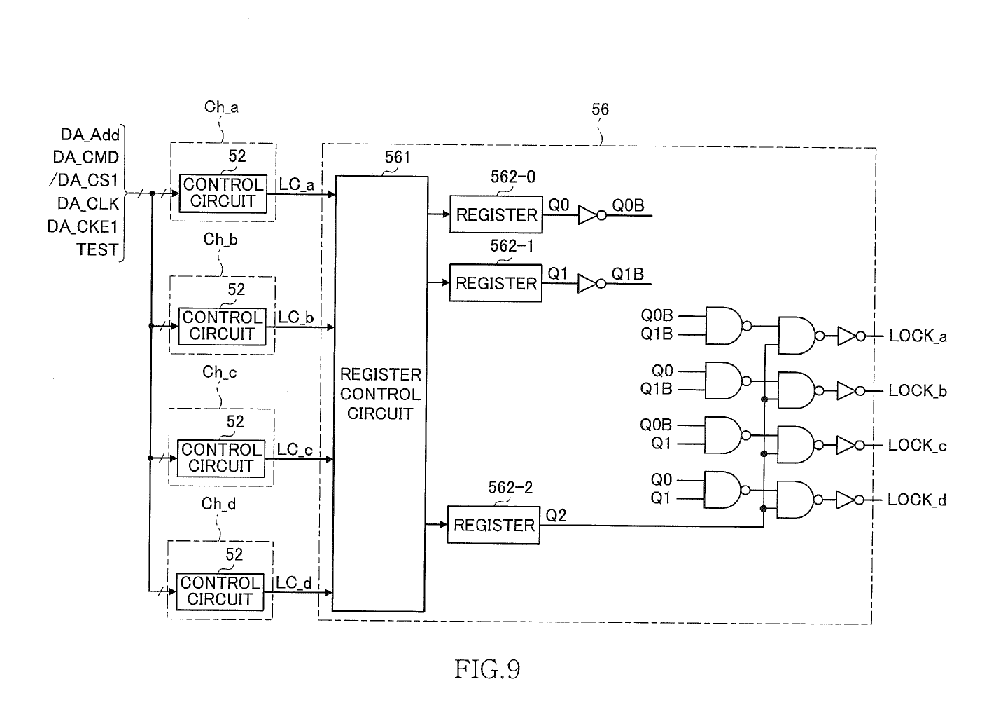

Turning to FIG. 8, the input circuit group 51 and the control circuit 52 include circuits other than those shown in the diagram. While only configurations related to the channel Ch_a are shown in FIG. 8, the remaining channels Ch_b to Ch_d have the same configuration. As shown in FIG. 8, the input circuit group 51 has switching circuits 511 to 515 corresponding to types of input signals, respectively. An example of internal configurations of the switching circuits 511 and 512 is shown in FIG. 8. Although internal configurations of the switching circuits 513 to 515 are not shown, the switching circuits 513 to 515 are configured to have the same internal configuration as that of the switching circuit 512. Various signals input or output through the terminals and processes related to these signals and performed by the semiconductor chip C2 are explained below in detail with reference to FIG. 8 as well as FIG. 7.

The clock enable terminal 34 is supplied with a clock enable signal CKE1 from the controller chip C0 shown in FIG. 1B in a normal operation mode. The test-clock enable terminal 44 is supplied with a test-clock enable signal DA_CKE1 (clock enable signal for testing) from the external tester while the chip unit test or the post-stack test is performed. The numeral “1” in the reference character indicates that the relevant signal corresponds to the semiconductor chip C2 (the first semiconductor chip counting from zero). The same applies to signals described later.

The clock enable terminal 34 and the test-clock enable terminal 44 are both connected to the switching circuit 511 included in the input circuit group 51 as shown in FIG. 8. The switching circuit 511 selects only one of these terminals in response to the test signal TEST mentioned above and connects the selected terminal to the control circuit 52. Specifically, the switching circuit 511 connects the test-clock enable terminal 44 to the control circuit 52 when the test signal TEST is activated and connects the clock enable terminal 34 thereto when the test signal TEST is deactivated. Accordingly, the test-clock enable signal DA_CKE1 is supplied to the control circuit 52 when the test signal TEST is activated and the clock enable signal CKE1 is supplied thereto when the test signal TEST is deactivated.

As shown in FIG. 8, the control circuit 52 has a power-down-signal generation circuit 521 that receives the clock enable signal (the clock enable signal CKE1 or the test-clock enable signal DA_CKE1) output from the input circuit group 51 and generates a power-down signal PD for turning off a power source of the corresponding channel. The power-down-signal generation circuit 521 is configured to start counting of a clock signal (an external clock signal CLK or a test clock signal DA_CLK, which will be explained in detail later) output from the input circuit group 51 in response to a change of the supplied clock enable signal from a high level to a low level and to activate the power-down signal PD when the count value reaches a predetermined value. The generated power-down signal PD is supplied to a power-supply control circuit 522 in the control circuit 52 and also to the switching circuits 512 to 515 in the input circuit group 51. The power-supply control circuit 522 supplies power to the circuits in the corresponding channel when the power-down signal PD is deactivated and stops supply of the power when the power-down signal PD is activated. Therefore, by bringing the power-down signal PD in an activate state, a power saving mode in which channel power consumption is low is realized.

The clock terminal 33 is supplied with the external clock signal CLK from the controller chip C0 in a normal operation mode. The test clock terminal 43 is supplied with the test-clock signal DA_CLK (clock signal for testing) from the external tester while the chip unit test or the post-stack test is performed.

The clock terminal 33 and the test clock terminal 43 are both connected to the switching circuit 512 included in the input circuit group 51 as shown in FIG. 8. The switching circuit 512 selects only one of these terminals in response to the test signal TEST to connect the selected terminal to the control circuit 52 only when the power-down signal PD mentioned above is deactivated. However, the switching circuit 512 is configured not to connect neither of the terminals to the control circuit 52 when the corresponding lock signal LOCK is activated, as in the case where the power-down signal PD is activated, even when the test clock terminal 43 is to be selected with the above configuration. Therefore, the test clock signal DA_CLK is supplied to the control circuit 52 only when the test signal TEST is activated and the power-down signal PD and the lock signal LOCK are both deactivated. When the test signal TEST and the power-down signal PD are both deactivated, the external clock signal CLK is supplied to the control circuit 52 regardless of a state of the lock signal LOCK. The control circuit 52 is configured to perform various processes mentioned later synchronously with the external clock signal CLK or the test clock signal DA_CLK supplied in this way. In other cases, it is preferable to fix an output terminal of the switching circuit 512 to a low level to prevent the control circuit 52 from performing an unexpected operation.

The following table 1 summarizes a relation among states of the test signal TEST, the power-down signal PD, and the lock signal LOCK and terminals to be connected to the control circuit 52 by the switching circuit 512. As is also clear from the table 1, the test clock terminal 43 is connected to the control circuit 52 only when the test signal TEST is activated and the power-down signal PD and the lock signal LOCK are both deactivated. Supply of the clock signal to the control circuit 52 is stopped when the test signal TEST is activated and the lock signal LOCK is activated. Therefore, the control circuit 52 cannot operate and thus the corresponding channel is brought into a forced-stop state (a lock state). As mentioned above, the lock signal LOCK is generated for each channel. Accordingly, by activating a given lock signal LOCK when performing the chip unit test or the post-stack test, the corresponding channel can be individually brought into the forced-stop state (the lock state).

TABLE 1

| TEST | PD | LOCK | Terminals to be connected to the control circuit 52 |
|---|---|---|---|
| H | H | H | None |
| H | H | L | None |
| H | L | H | None |
| H | L | L | The test clock terminal 43 |
| L | H | H | None |
| L | H | L | None |
| L | L | H | The clock terminal 33 |
| L | L | L | The clock terminal 33 |

The chip select terminal 32 is supplied with a chip select signal /CS1 from the control chip C0 in a normal operation mode. The test-chip select terminal 42 is supplied with a test-chip select signal /DA_CS1 (chip select signal for testing) from the external tester while the chip unit test or the post-stack test is performed. In this case, “/ (slash)” attached at the top of the reference character indicates that the relevant signal is a low-active signal. The same applies to signals described later.

The chip select terminal 32 and the test-chip select terminal 42 are both connected to the switching circuit 513 included in the input circuit group 51 as shown in FIG. 8. As the switching circuit 512, the switching circuit 513 selects only one of these terminals in response to the test signal TEST to connect the selected terminal to the control circuit 52 only when the power-down signal PD is deactivated. However, the switching circuit 513 is configured not to connect neither of the terminals to the control circuit 52 when the corresponding lock signal LOCK is activated, as in the case where the power-down signal PD is activated, even when the test-chip select terminal 42 is to be selected with the above configuration. Therefore, only when the test signal TEST is activated and the power-down signal PD and the lock signal LOCK are both deactivated, the test-chip select signal /DA_CS1 is supplied to the control circuit 52. When the test signal TEST and the power-down signal PD are both deactivated, the chip select signal /CS1 is supplied to the control circuit 52 regardless of a state of the lock signal LOCK. In other cases, it is preferable to fix an output terminal of the switching circuit 513 to a low level as in the switching circuit 512.

The command terminal 31 is supplied with a command signal CMD from the controller chip C0 in a normal operation mode. The test command terminal 41 is supplied with a test command signal DA_CMD (command signal for testing) from the external tester while the chip unit test or the post-stack test is performed. Specifically, the command signal CMD is composed of three lines of signals /RAS, /CAS, and /WE and the test command signal DA_CMD is composed of three lines of signals /DA_RAS, /DA_CAS, and /DA_WE. Various commands used in the general DRAM are expressed by combinations of states of these three signal lines. Furthermore, in the first embodiment, a channel-specific test-mode entry signal indicating an entry to a channel-specific test mode (a mode in which a test for each channel is performed) and a channel-specific test-mode exit signal indicating an exit from the channel-specific test mode are also expressed by combinations of states of /DA_RAS, /DA_CAS, /DA_WE, and DA_Add.

The command terminal 31 and the test command terminal 41 are both connected to the switching circuit 514 included in the input circuit group 51 as shown in FIG. 8. The switching circuit 514 selects only one of these terminals in response to the test signal TEST to connect the selected terminal to the control circuit 52 only when the power-down signal PD is deactivated, as the switching circuits 512 and 513. However, the switching circuit 514 is configured not to connect neither of the terminals to the control circuit 52 when the corresponding lock signal LOCK is activated, as in the case where the power-down signal PD is activated, even when the test command terminal 41 is to be connected with the above configuration. Therefore, the test command signal DA_CMD is supplied to the control circuit 52 only when the test signal TEST is activated and the power-down signal PD and the lock signal LOCK are both deactivated. When the test signal TEST and the power-down signal PD are both deactivated, the command signal CMD is supplied to the control circuit 52 regardless of a state of the lock signal LOCK. In other cases, it is preferable to fix an output terminal of the switching circuit 514 to a low level as in the switching circuits 512 and 513.

The address terminal 30 is supplied with an address signal Add from the controller chip C0 in a normal operation mode. The test address terminal 40 is supplied with a test address signal DA_Add (address signal for testing) from the external tester when the chip unit test or the post-stack test is performed.

The address terminal 30 and the test address terminal 40 are both connected to the switching circuit 515 included in the input circuit group 51 as shown in FIG. 8. The switching circuit 515 selects only one of these terminals in response to the test signal TEST to connect the selected terminal to the control circuit 52 only when the power-down signal PD is deactivated, as the switching circuits 512 to 514. However, the switching circuit 515 is configured not to connect neither of the terminals to the control circuit 52 when the corresponding lock signal LOCK is activated, as in the case where the power-down signal PD is activated, even when the test address terminal 40 is to be selected with the above configuration. Therefore, the test address signal DA_Add is supplied to the control circuit 52 only when the test signal TEST is activated and the power-down signal PD and the lock signal LOCK are both deactivated. When the test signal TEST and the power-down signal PD are both deactivated, the address signal Add is supplied to the control circuit 52 regardless of a state of the lock signal LOCK. In other cases, it is preferable to fix an output terminal of the switching circuit 515 to a low level as in the switching circuits 512 to 514.

An operation of the control circuit 52 having received the signals in this way is explained. The control circuit 52 is configured to receive the command signal (the command signal CMD or the test command signal DA_CMD) supplied through the switching circuit 514 and the address signal (the address signal Add or the test address signal DA_Add) supplied through the switching circuit 515 only when the chip select signal (the chip select signal /CS1 or the test-chip select signal /DA_CS1 corresponding to the semiconductor chip C2) supplied through the switching circuit 513 is activated (at a low level). The control circuit 52 has a function to generate various kinds of internal commands such as an act command, a write command, and a read command, a switching signal SW, and a control signal LC based on the command signal and the address signal received in this way.

The switching signal SW is a signal indicating the test-data input/output terminal 46 in a case where the test signal TEST is activated (while the chip unit test or the post-stack test is performed) and indicating the data input/output terminal 35 in other cases. The switching signal SW generated by the control circuit 52 is supplied to the switching circuit 55. The switching circuit 55 connects a terminal indicated by the switching signal SW to the data input/output circuit 54.

The control circuit 52 has a function to control the memory cell array 53 based on the generated various internal commands. Accordingly, at the time of read, read data that is read from the memory cell array 53 is output from the data input/output terminal 35 or the test-data input/output terminal 46 via the data input/output circuit 54 and the switching circuit 55. At the time of write, write data that is input from the data input/output terminal 35 or the test-data input/output terminal 46 is written to the memory cell array 53 via the switching circuit 55 and the data input/output circuit 54.

The control signal LC is a signal indicating one or plural channels to be locked.

Specific information (a lock control signal) indicating one or plural channels to be locked is supplied from the tester to the control circuit 52 using the test address signal DA_Add. The control circuit 52 generates the control signal LC indicating one or plural channels indicated by the lock control signal when the test command signal DA_CMD and the test address signal DA_Add correspond to the channel-specific test-mode entry signal mentioned above, and supplies the generated control signal LC to the channel-specific test-mode control circuit 56. The channel-specific test-mode control circuit 56 generates the lock signals LOCK_a to LOCK_d mentioned above based on the supplied control signal LC. The control circuit 52 generates the control signal LC indicating unlock of all the channels when the test command signal DA_CMD and the test address signal DA_Add correspond to the channel-specific test-mode exit signal mentioned above, and supplies the generated control signal LC to the channel-specific test-mode control circuit 56. The channel-specific test-mode control circuit 56 having received the control signal LC deactivates all of the lock signals LOCK_a to LOCK_d, thereby unlocking all of the channels Ch_a to Ch_d. The operation of the channel-specific test-mode control circuit 56 is explained in detail below.

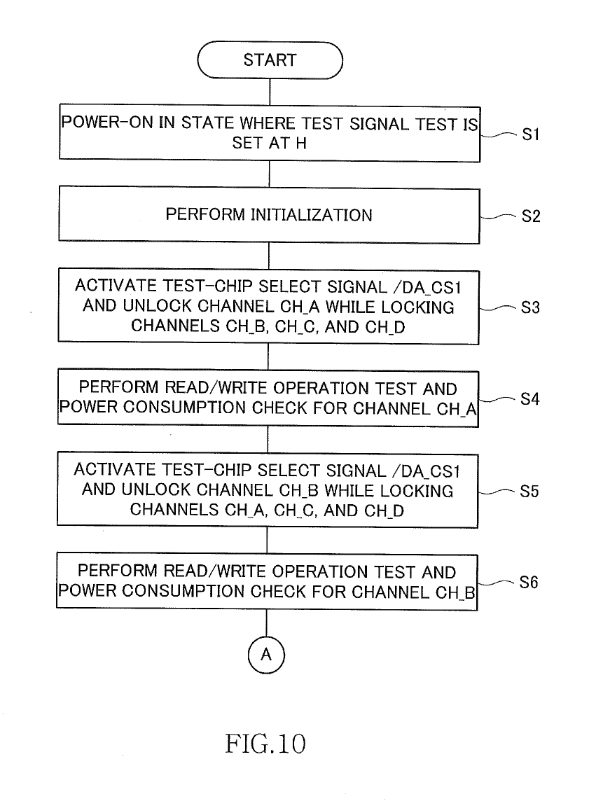

As shown in FIG. 9, the channel-specific test-mode control circuit 56 has a register control circuit 561 and three registers 562-0 to 562-2. The register control circuit 561 receives the control signals LC_a to LC_d from the control circuits 52 of the corresponding channels and controls memory contents of the registers 562-0 to 562-2 based on any one of the received control signals. The channel-specific test-mode control circuit 56 has a function to select a channel to be locked based on the memory contents of the registers 562-0 to 562-2 controlled in this way and to generate the lock signals LOCK_a to LOCK_d to lock the selected channel.

In this case, contents of the control signals LC_a to LC_d are the same. The reason why the control circuits 52 of the respective channels generate the control signals LC with the same contents is that the control circuit 52 of a channel in a lock state cannot generate the control signal LC. Therefore, the resister control circuit 561 is preferably configured to select the control signal LC generated by the control circuit 52 of an unlocked channel and to control the memory contents of the registers 562-0 to 562-2 based on the selected control signal LC.

The following table 2 shows a correspondence relation of lock target channels, data Q0 to Q2 that is the memory contents of the registers 562-0 to 562-2, respectively, and states of the lock signals LOCK_a to LOCK_d. As is clear from the table 2, the locking operation in the semiconductor device 1 is either locking three channels except for one channel or unlocking all the channels. A lock control based on the states of the lock signals LOCK_a to LOCK_d controlled in this way is realized by the switching circuit 512 and the like of the input circuit group 51 as mentioned above.

TABLE 2

| lock target | Q0 | Q1 | Q2 | LOCK_a | LOCK_b | LOCK_c | LOCK_d |
|---|---|---|---|---|---|---|---|
| Ch_b, Ch_c, Ch_d | 0 | 0 | 1 | L | H | H | H |
| Ch_a, Ch_c, Ch_d | 1 | 0 | 1 | H | L | H | H |
| Ch_a, Ch_b, Ch_d | 0 | 1 | 1 | H | H | L | H |
| Ch_a, Ch_b, Ch_c | 1 | 1 | 1 | H | H | H | L |
| — | 0 or 1 | 0 or 1 | 0 | L | L | L | L |

As explained above, with the semiconductor device 1 according to the first embodiment, given channels can be locked by the test command signal DA_CMD and the test address signal DA_Add supplied from a tester. Accordingly, when a test (the chip unit test or the post-stack test) on a semiconductor chip having plural channels is performed through a test terminal connected in common to the channels, a test for each channel (a test in a state where only one channel is operated) can be performed. Therefore, a defective product (for example, a defective product in which the current is too large only in one channel and the current is too small in the remaining three channels as mentioned above) that may be missed by a test in a state where all the channels are operated alone can be detected.

Furthermore, the semiconductor device 1 according to the present embodiment supports an entry into the channel-specific test mode and an exit from the channel-specific test mode. Accordingly, as well as the test for each channel, the conventional test in a state where all the channels are operated can be also performed.

With the semiconductor device 1 according to the present embodiment, not only the test clock terminal 43 but also the test-chip select terminal 42, the test command terminal 41, and the test address terminal 40 are unconnected to the control circuit 52 of a channel in a lock state. Therefore, an erroneous operation of the control circuit 52 due to supply of an unexpected signal through these terminals is prevented.

A test method for the semiconductor device 1 having the configuration mentioned above is explained next with reference to flowcharts of tests.

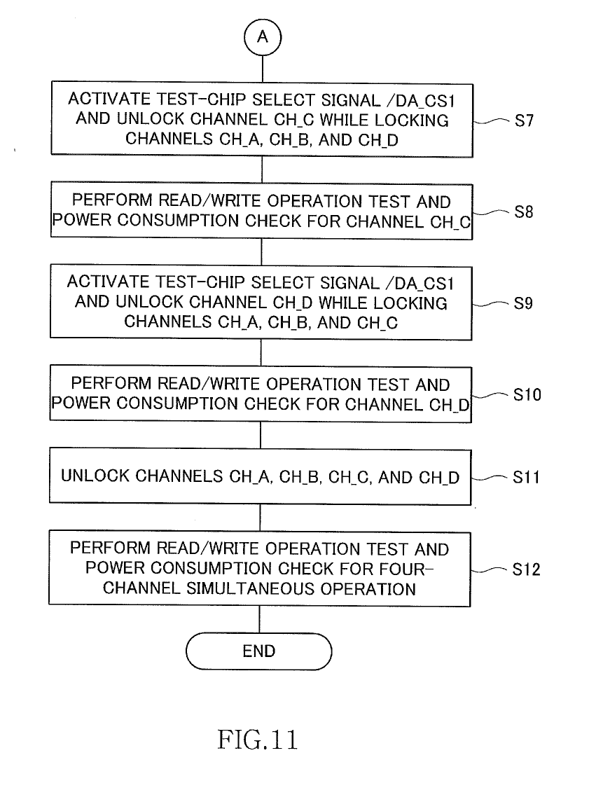

Turning to FIGS. 10 and 11, while the flowcharts show a case where the semiconductor chip C2 is a test target as an example, the same processing is performed when other semiconductor chips are test targets. As mentioned above, the test shown in FIGS. 10 and 11 is performed by supplying the various kinds of control signals from the tester in a state where the probe needle of the tester is brought into contact with the test pads TP. The test pads TP brought into contact with the probe needle are those formed on the principal surface of the semiconductor chip C2 as the test target when the chip unit test is performed, and are those formed on the principal surface C1a of the semiconductor chip C1 (see FIG. 1A) located on the lowermost layer when the post-stack test is performed.

In this test, the test signal TEST is set at a high level (an activated state) first, and the semiconductor chip C2 is powered on in this state (Step S1). The semiconductor chip C2 is then initialized (Step S2). Specifically, the test reset signal being a low-active signal is first kept at a low level (an activated state) for 200 nanoseconds or more and then returned to a high level (a deactivated state). The test-clock enable signal DA_CKE1 is then kept at a low level for 500 nanoseconds or more. During that time, toggling of the test clock signal DA_CLK is started. The test-clock enable signal DA_CKE1 is then returned to a high level and then the test command signal DA_CMD indicating an NOP command is supplied. By the processes mentioned above, initialization of the semiconductor chip C2 is completed.

The channel Ch_a (first memory unit) is then unlocked while the channels Ch_b (second memory unit), Ch_c, and Ch_d are locked (Step S3). Specifically, the test-chip select signal /DA_CS1 corresponding to the semiconductor chip C2 as the test target is activated, and the tester supplies the channel-specific test-mode entry signal and a lock control signal (first lock control signal) indicating the channels Ch_b, Ch_c, and Ch_d as lock targets through the test command terminal 41 and the test address terminal 40. Accordingly, the channel-specific test-mode control circuit 56 controls the lock signals LOCK_a to LOCK_d to a low level, a high level, a high level, and a high level, respectively, so that unlocking of the channel Ch_a and locking of the channels Ch_b, Ch_c, and Ch_d is realized.

The test command signal DA_CMD, the test address signal DA_Add, and the like are then supplied from the tester, thereby performing a read/write operation test and a power consumption check (Step S4). At that time, the channels Ch_b, Ch_c, and Ch_d are locked and thus the test is performed in a state where only the channel Ch_a is operated.

The same processes as those at Steps S3 and S4 mentioned above are then performed while the channel as the lock target is changed. Specifically, a test in a state where the channel Ch_b is unlocked while the channels Ch_a, Ch_c, and Ch_d are locked by activating the test-chip select signal /DA_CS1 and supplying the channel-specific test-mode entry signal and a lock control signal (second lock control signal) indicating the channels Ch_a, Ch_c, and Ch_d as lock targets from the tester through the test command terminal 41 and the test address terminal 40 (Steps S5 and S6), a test in a state where the channel Ch_c is unlocked while the channels Ch_a, Ch_b, and Ch_d are locked by activating the test-chip select signal /DA_CS1 and supplying the channel-specific test-mode entry signal and a lock control signal indicating the channels Ch_a, Ch_b, and Ch_d as lock targets from the tester through the test command terminal 41 and the test address terminal 40 (Steps S7 and S8), and a test in a state where the channel Ch_d is unlocked while the channels Ch_a, Ch_b, and Ch_c are locked by activating the test-chip select signal /DA_CS1 and supplying the channel-specific test-mode entry signal and a lock control signal indicating the channels Ch_a, Ch_b, and Ch_c as lock targets from the tester through the test command terminal 41 and the test address terminal 40 (Steps S9 and S10) are sequentially performed.

Lastly, the read/write operation test and the power consumption check are performed in a state where all the channels Ch_a to Ch_d are unlocked by supplying the channel-specific test-mode exit signal from the tester through the test command terminal 41 (Steps S11 and S12). This completes the chip unit test.

As explained above, by the test method for the semiconductor device 1 according to the first embodiment, the test is performed while given channels are locked by supplying the channel-specific test-mode entry signal and the lock control signal from the tester, which enables the tests for the respective channels to be performed in turn with respect to each of the channels. Because the test is lastly performed in a state where all the channels are unlocked, the test in a state where all the channels are operated can be also performed.

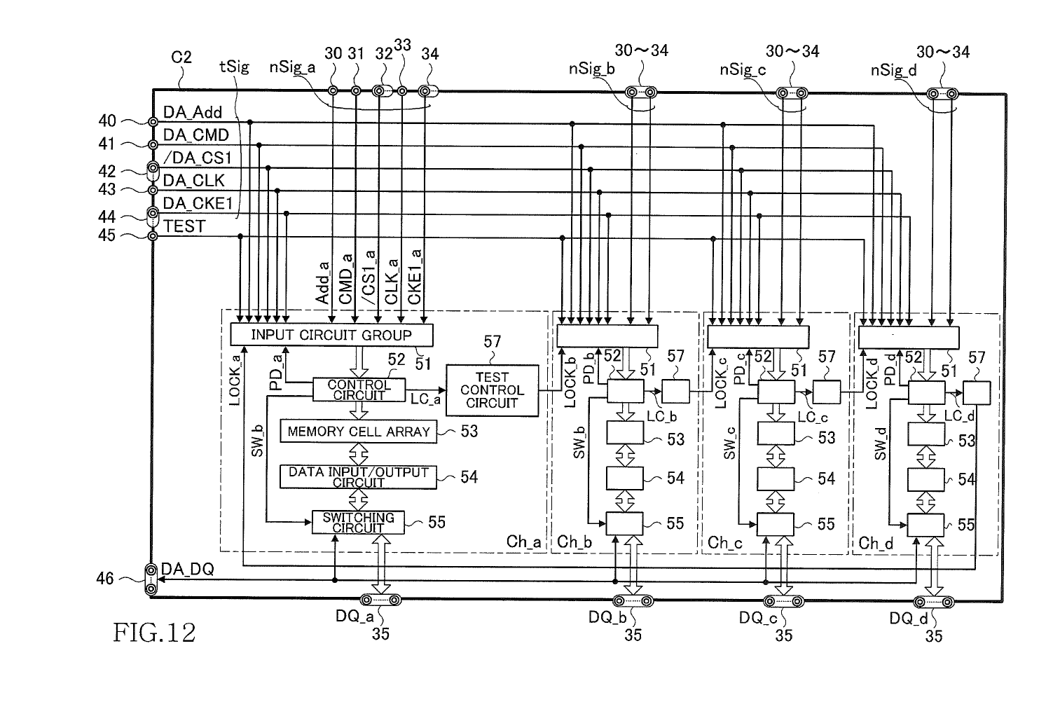

Turning to FIG. 12, the semiconductor device 1 according to the second embodiment of the present invention is different from the semiconductor device 1 according to the first embodiment in that a test control circuit 57 is provided in each of the semiconductor chips for each of the channels Ch_a to Ch_d instead of the channel-specific test-mode control circuit 56 (FIG. 7), and other features of the semiconductor device 1 according to the second embodiment are identical to those of the semiconductor device 1 according to the first embodiment. The difference is mainly explained below.

As shown in FIG. 12, the channels Ch_a to Ch_d according to the second embodiment each have the test control circuit 57 (sub-test control circuit). In the second embodiment, these test control circuits 57 constitute a test control circuit that locks some of the channels Ch_a to Ch_d in response to the lock control signal supplied from the tester.

In the second embodiment, the channels Ch_a to Ch_d are ranked cyclically and each of the test control circuits 57 is configured to lock a channel ranked to follow the corresponding channel. In an example shown in FIG. 12, the channels are ranked in the order of the channel Ch_a, the channel Ch_b, the channel Ch_c, the channel Ch_d, the channel Ch_a, ???. Therefore, the test control circuit 57 of the channel Cha locks the channel Ch_b, the test control circuit 57 of the channel Ch_b locks the channel Ch_c, the test control circuit 57 of the channel Ch_c locks the channel Ch_d, and the test control circuit 57 of the channel Ch_d locks the channel Ch_a.

When locking by the test control circuit 57 is performed, the channel-specific test-mode entry signal and a lock control signal indicating a channel as a lock target are supplied from the tester through the test command terminal 41 and the test address terminal 40 as in the first embodiment. The control circuit 52 of each channel generates the control signal LC and supplies the generated control signal LC to the corresponding test control circuit 57, only when a channel ranked to follow the corresponding channel is indicated as the lock target by the supplied lock control signal. The test control circuit 57 having received the control signal LC generates a lock signal LOCK for locking the indicated channel and supplies the generated lock signal LOCK to the input circuit group 51 of the target channel. The test control circuit 57 is preferably configured to have, for example, a register circuit that holds either 0 or 1 according the control signal LC and to perform an activation state control of the lock signal LOCK in response to the data held in the register circuit.

Specific contents of the lock signal LOCK and processes performed by the input circuit group 51 having received the lock signal LOCK are the same as those explained in the first embodiment. Therefore, also with the semiconductor device 1 according to the second embodiment, when the chip unit test or the post-stack test is to be performed through the test terminal connected in common to the channels, the test for each of the channels can be performed.

However, when locking and unlocking of the channels according to the second embodiment is to be performed, the target channels need to be processed sequentially one by one. Furthermore, the order of locking and unlocking needs to be noted. This point is explained below.

When a certain channel is to be locked in the semiconductor device 1 according to the second embodiment, the lock signal LOCK is supplied from a channel immediately before the lock target channel, as mentioned above. This means that when a relatively subsequent channel is to be locked, a relatively previous channel needs to be operated. Therefore, channel locking needs to be performed sequentially one by one in a direction opposite to the rank order of the channels.

This is explained with reference to the example shown in FIG. 12. In this example, a direction from the channel Ch_a to the channel Ch_d is the forward direction. Therefore, the opposite direction is a direction from the channel Ch_d to the channel Ch_a. For example, when the channels Ch_a to Ch_c are lock targets, the lock control signal indicating the channel Ch_c is first supplied, thereby locking the channel Ch_c through the channel Ch_b. The lock control signal indicating the channel Ch_b is then supplied, thereby locking the channel Ch_b through the channel Ch_a. Lastly, the lock signal indicating the channel Ch_a is supplied, thereby locking the channel Ch_a through the channel Ch_d. By locking the channels sequentially one by one in the opposite direction to the rank order of the channels in this way, locking of desired channels can be realized.

The same applies to unlocking. In this case, the channels need to be unlocked sequentially one by one in the forward direction of the rank order of the channels. In this way, unlocking of desired channels can be realized.

As explained above, also with the semiconductor device 1 according to the second embodiment, given channels can be locked by the test command signal DA_CMD and the test address signal DA_Add supplied from the tester, so that when the chip unit test or the post-stack test is to be performed through the test terminal connected in common to the respective channels, the test for each of the channels can be performed.

Furthermore, although the test control circuit 57 that performs locking is provided in each of channels that may be lock targets, locking and unlocking of desired channels can be realized.

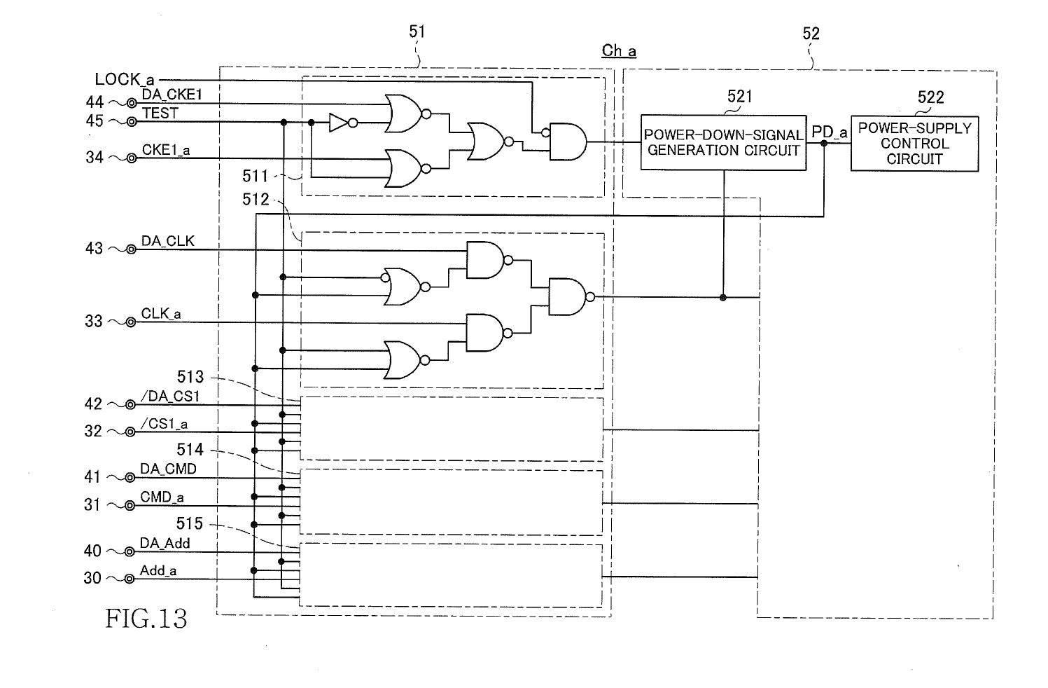

Turning to FIG. 13, the semiconductor device 1 according to the third embodiment of the present invention is different from the semiconductor device 1 according to the first embodiment in that an input destination of the lock signal LOCK in the input circuit group 51 is the switching circuit 511, and other features of the semiconductor device 1 according to the third embodiment are identical to those of the semiconductor device 1 according to the first embodiment. The difference is mainly explained below.

As shown in FIG. 13, in the input circuit group 51 according to the third embodiment, the lock signal LOCK is supplied only to the switching circuit 511. The switching circuit 511 is configured to select only one of the clock enable terminal 34 and the test-clock enable terminal 44 in response to the test signal TEST as in the first embodiment but to connect the selected terminal to the control circuit 52 only when the corresponding lock signal LOCK is deactivated unlike the first embodiment. Accordingly, the test-clock enable signal DA_CKE1 is supplied to the control circuit 52 when the test signal TEST is activated and the corresponding lock signal LOCK is deactivated, and the clock enable signal CKE1 is supplied to the control circuit 52 when the test signal TEST is deactivated and the corresponding lock signal LOCK is deactivated. When the corresponding lock signal LOCK is activated, none of the clock enable signals is supplied to the control circuit 52.

As mentioned above, with the semiconductor device 1 according to the third embodiment, supply of the clock enable signal to the control circuit 52 can be stopped by activating the lock signal LOCK. Therefore, also with the semiconductor device 1 according to the third embodiment, similarly to the first and second embodiments, channel locking can be realized.

It is preferable to fix the output terminal of the switching circuit 511 to a low level when the corresponding lock signal LOCK is activated. Accordingly, the power-down-signal generation circuit 521 activates the power-down signal PD after a predetermined time has passed from activation of the lock signal LOCK. Therefore, other terminals (such as the chip select terminal 32 and the test-chip select terminal 42) are then also disconnected from the control circuit 52, so that an erroneous operation of the control circuit 52 due to supply of an unexpected signal can be prevented. Furthermore, with this configuration, lock target channels are brought into a power saving mode and thus power consumption of a test target channel can be measured more accurately.

It is apparent that the present invention is not limited to the above embodiments, but may be modified and changed without departing from the scope and spirit of the invention.

In the above embodiments, examples in which the present invention is applied to the semiconductor device 1 having four stacked semiconductor chips have been explained. However, the present invention can be applied to any type of semiconductor devices regardless of the number of stacked chips (including one) as long as the semiconductor device needs to perform a test of semiconductor chips each having a plurality of channels through a test terminal connected in common to the channels.

In the above embodiments, the chip unit test and the post-stack test have been explained in detail. However, tests of the semiconductor device to which the present invention can be applied are not limited thereto. For example, also in the composite semiconductor device 10 shown in FIG. 1B, an identical test can be performed by applying various kinds of test signals to external terminals of the composite semiconductor device 10 corresponding to the direct access terminals of the semiconductor chips in a state where the composite semiconductor device 10 is mounted on a test board or the like and is connected to a tester.

It is apparent that the present invention is not limited to the above embodiments, but may be modified and changed without departing from the scope and spirit of the invention.

1. A semiconductor device including a semiconductor chip, the semiconductor chip comprising:
a plurality of memory units each including a plurality of memory cells;
a plurality of pad groups each coupled to a corresponding one of the memory units and each including a plurality of pads; and
a plurality of test pads each coupled in common to the memory units;
in a normal operation mode, the test pads being free from signals and the pads of each of the pad groups being supplied with signals such that normal operations are performed respectively on the memory units;
in a test operation mode, the test pads being supplied with test signals and the pads of each of the pad groups being free from signals such that test operations are performed respectively on the memory units.

2. The semiconductor device as claimed in claim 1, wherein the semiconductor chip further comprises a semiconductor substrate and a plurality of penetration electrodes each penetrating the semiconductor substrate, each of the pads of each of the pad groups being coupled to an associated one of the penetration electrodes, and each of the test pads being disconnected from any of the penetration electrodes.

3. The semiconductor device as claimed in claim 1, wherein the pads of each of the pad groups are substantially equal in size to each other and the test pads are substantially equal in size to each other.

4. The semiconductor device as claimed in claim 3, wherein the pads of each of the pad groups are different in size from the test pads.

5. The semiconductor device as claimed in claim 4, wherein the pads of each of the pad groups are smaller in size than the test pads.

6. The semiconductor device as claimed in claim 1, further including an additional semiconductor chip, the additional semiconductor chip comprising:
a plurality of additional memory units each including a plurality of additional memory cells;
a plurality of additional pad groups each coupled to a corresponding one of the additional memory units and each including a plurality of additional pads; and
a plurality of additional test pads each coupled in common to the additional memory units;
in the normal operation mode, the additional test pads being free from signals and the additional pads of each of the additional pad groups being supplied with signals such that normal operations are performed respectively on the additional memory units;
in the test operation mode, the test pads being supplied with test signals and the additional pads of each of the pad groups being free from signals such that test operations are performed respectively on the additional memory units.

7. The semiconductor device as claimed in claim 6, wherein the additional semiconductor chip is stacked on the semiconductor chip.

8. The semiconductor device as claimed in claim 7, wherein each of the additional pads of each of the additional pad groups is coupled to an associated one of the pads of each of the pad groups.

9. The semiconductor device as claimed in claim 7, wherein the semiconductor chip further comprises a semiconductor substrate and a plurality of penetration electrodes each penetrating the semiconductor substrate, each of the pads of each of the pad groups being coupled to an associated one of the penetration electrodes, and each of the test pads being disconnected from any of the penetration electrodes.

10. The semiconductor device as claimed in claim 9, wherein each of the additional pads of each of the additional pad groups is coupled to an associated one of the penetration electrodes.

11. The semiconductor device as claimed in claim 9, wherein each of the additional pads of each of the additional pad groups are vertically aligned with an associated one of the penetration electrodes and an associated one of the pads of each of the pad groups respectively.

12. The semiconductor device as claimed in claim 11, wherein each of the additional pads of each of the additional pad groups is coupled to an associated one of the penetration electrodes.

13. The semiconductor device as claimed in claim 6, wherein each of the additional pads of each of the additional pad groups is coupled to an associated one of the pads of each of the pad groups.
